(19) United States
(12) Patent Application Publication
(10) Pub. No.: US 2025/0343180 A1
(43) Pub. Date: Nov. 6, 2025

(54) SEMICONDUCTOR DEVICE AND METHOD FOR MANUFACTURING SEMICONDUCTOR DEVICE

(71) Applicant: Rohm Co., Ltd., Kyoto-shi (JP)

(72) Inventor: Hiroshi OKUMURA, Kyoto-shi (JP)

(21) Appl. No.: 19/193,393

(22) Filed: Apr. 29, 2025

(30) Foreign Application Priority Data
May 2, 2024 (JP) 2024-074869

(51) Int. Cl. H01L 23/00

(52) U.S. Cl. CPC H01L 24/05; H01L 24/03; H01L 24/11; H01L 24/13; H01L 24/14; H01L 2224/02317; H01L 2224/02331; H01L 2224/02379; H01L 2224/03462; H01L 2224/0401; H01L 2224/05024; H01L 2224/05027; H01L 2224/11462; H01L 2224/13022; H01L 2224/13111; H01L 2224/1403; H01L 2224/14051; H01L 2224/1411

(57) ABSTRACT

A semiconductor device includes a semiconductor element, an electrode on a first side in a thickness direction of the semiconductor element, a re-wiring connected to the electrode, a terminal connected to the re-wiring, and a conductive bonding layer connected to the terminal. The terminal includes a first terminal and a second terminal. The conductive bonding layer includes a first conductive bonding layer connected to the first terminal and a second conductive bonding layer connected to the second terminal. The area of the second terminal is greater than the area of the first terminal. The area of the second conductive bonding layer is greater than the area of the first conductive bonding layer.

### FIELD

The present disclosure relates to a semiconductor device and a method for manufacturing a semiconductor device.

### BACKGROUND

JP-A-2014-165335 discloses an example of a semiconductor device. The semiconductor device includes a substrate having an element forming surface, a pad terminal disposed on the element forming surface, a passivation film covering a portion of the pad terminal and the element forming surface, a Cu re-wiring extending from the pad terminal, an organic coating film covering the Cu re-wiring, and a resin film covering the organic coating film. When the semiconductor device having the configuration described above is to carry large electric current, the electrical resistance is reduced by increasing the area of the Cu re-wiring in plan view. As semiconductor devices are designed to have higher current capacities, further reduction in electrical resistance may be desirable.

### DRAWINGS

FIG. 1 is a plan view of a semiconductor device according to a first embodiment of the present disclosure.

FIG. 2 is a plan view corresponding to FIG. 1, with the illustration of a plurality of terminals and a plurality of conductive layers omitted.

FIG. 3 is a plan view corresponding to FIG. 2, with the illustration of a second insulating film omitted.

FIG. 4 is a partially enlarged sectional view taken along line IV-IV in FIG. 1.

FIG. 5 is a partially enlarged sectional view taken along line V-V in FIG. 1.

FIG. 6 is a sectional view illustrating a step of a method for manufacturing a semiconductor device according to the first embodiment of the present disclosure.

FIG. 7 is a sectional view illustrating a step subsequent to FIG. 6.

FIG. 8 is a sectional view illustrating a step subsequent to FIG. 7.

FIG. 9 is a sectional view illustrating a step subsequent to FIG. 8.

FIG. 10 is a sectional view illustrating a step subsequent to FIG. 8.

FIG. 11 is a sectional view illustrating a step subsequent to FIG. 9.

FIG. 12 is a sectional view illustrating a step subsequent to FIG. 11.

FIG. 13 is a sectional view illustrating a step subsequent to FIG. 12.

FIG. 14 is a sectional view illustrating a step subsequent to FIG. 12.

FIG. 15 is a sectional view illustrating a step subsequent to FIG. 13.

FIG. 16 is a sectional view illustrating a step subsequent to FIG. 14.

FIG. 17 is a sectional view illustrating a step subsequent to FIG. 15.

FIG. 18 is a sectional view illustrating a step subsequent to FIG. 16.

FIG. 19 is a sectional view illustrating a step subsequent to FIG. 17.

FIG. 20 is a sectional view illustrating a step subsequent to FIG. 18.

FIG. 21 is a sectional view illustrating a step subsequent to FIG. 19.

FIG. 22 is a sectional view illustrating a step subsequent to FIG. 20.

FIG. 23 is a sectional view illustrating a step subsequent to FIG. 21.

FIG. 24 is a sectional view illustrating a step subsequent to FIG. 22.

FIG. 25 is a sectional view illustrating a step subsequent to FIG. 23.

FIG. 26 is a sectional view illustrating a step subsequent to FIG. 24.

FIG. 27 is a plan view of a semiconductor device according to a second embodiment of the present disclosure.

FIG. 28 is a plan view corresponding to FIG. 27, with the illustration of a plurality of terminals and a plurality of conductive layers omitted.

FIG. 29 is a sectional view, similar to FIG. 4, of a semiconductor device according to a third embodiment of the present disclosure.

FIG. 30 is a sectional view, similar to FIG. 5, of a semiconductor device according to the third embodiment of the present disclosure.

### EMBODIMENTS

The following specifically describes preferred embodiments of the present disclosure with reference to the drawings.

In the following description, the same or similar elements are indicated by the same reference numerals, and redundant descriptions are omitted. In the present disclosure, the terms such as “first”, “second”, “third”, and so on are used only as labels and not to imply any order of the items referred to by the terms.

In the present disclosure, the expressions “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expressions “An object A is arranged in an object B”, and “An object A is arranged on an object B” imply the situation where, unless otherwise specifically noted, “the object A is arranged directly in or on the object B”, and “the object A is arranged in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a portion of the object B”. Still further, the expression “An object A contains (or the material of an object A includes) a material C” implies the situation where, unless otherwise specifically noted, “the object A is made of (or the material of the object A is) the material C” or “the object A is mainly made of (or the material of the object A is) the material C”. Still further, “A surface A faces in a direction B (or toward a first side or an opposite second side in the direction B) is not limited, unless otherwise specifically noted, to the situation where the surface A forms an angle of 90° with the direction B but includes the situation where the surface A is inclined relative to the direction B.

### First Embodiment

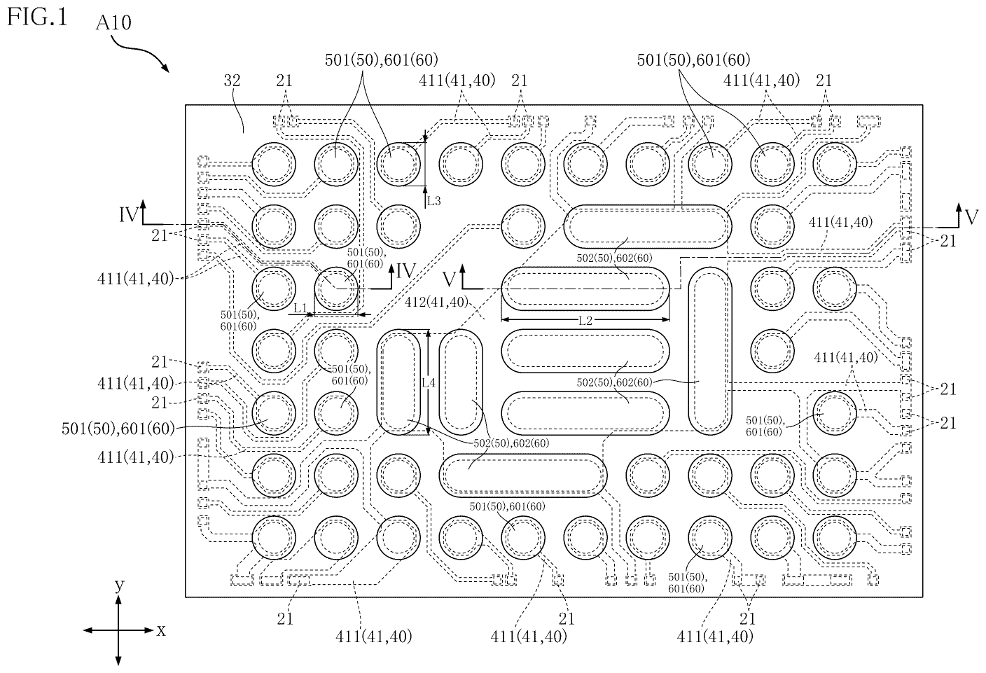

With reference to FIGS. 1 to 5, the following describes a semiconductor device A10 according to a first embodiment of the present disclosure. The semiconductor device A10 may be large-scale integration (LSI) that uses what is called wafer-level chip size package (WL-CSP). The semiconductor device A10 includes a semiconductor element 10, a plurality of electrodes 21, a passivation film 22, a first insulating film 31, a second insulating film 32, a plurality of re-wiring 40, a plurality of terminals 50, and a plurality of conductive bonding layers 60.

For convenience of description, reference is made to a thickness direction z, a first direction x, and a second direction y, which are perpendicular to each other. The thickness direction z corresponds to the thickness direction of the semiconductor device A10. Additionally, “in plan view” refers to a view as seen in the thickness direction z. The first direction x is perpendicular to the thickness direction z. The second direction y is perpendicular to the thickness direction z and the first direction x. One side in the thickness direction z is referred to as the z1 side in the thickness direction z, and the other side as the z2 in the thickness direction z. The z1 side in the thickness direction z may be referred to as the upper side, and the z2 side as the lower side. Note, however, that the terms, such as “top”, “bottom”, “upper”, “lower”, “upper surface”, and “lower surface” are used to describe the relative positions of elements in the thickness direction z, and not necessarily describe their positions with respect to the direction of gravity.

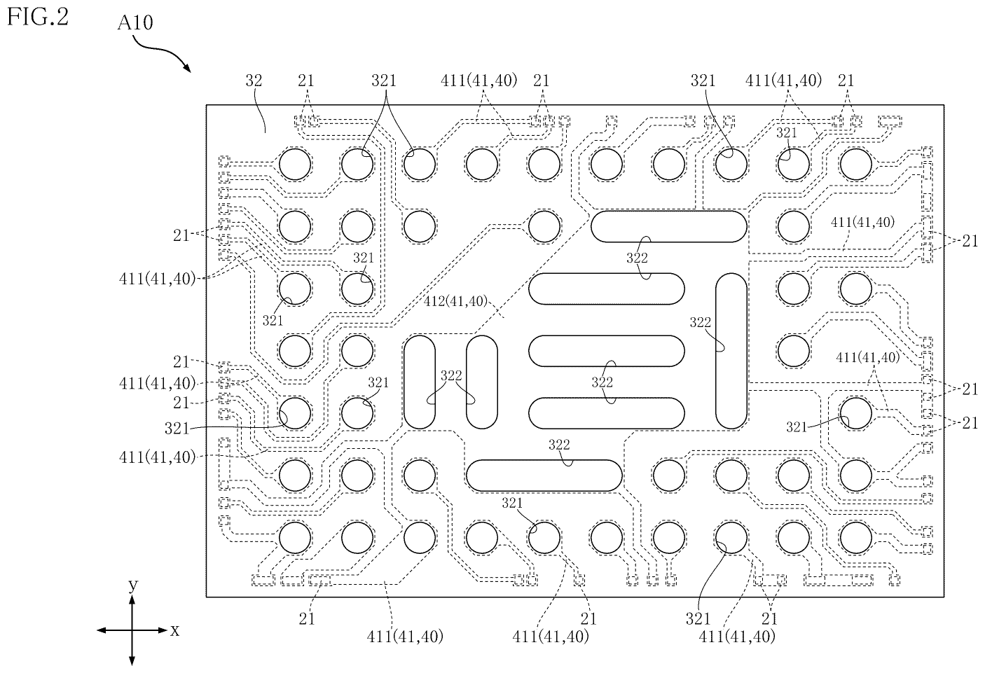

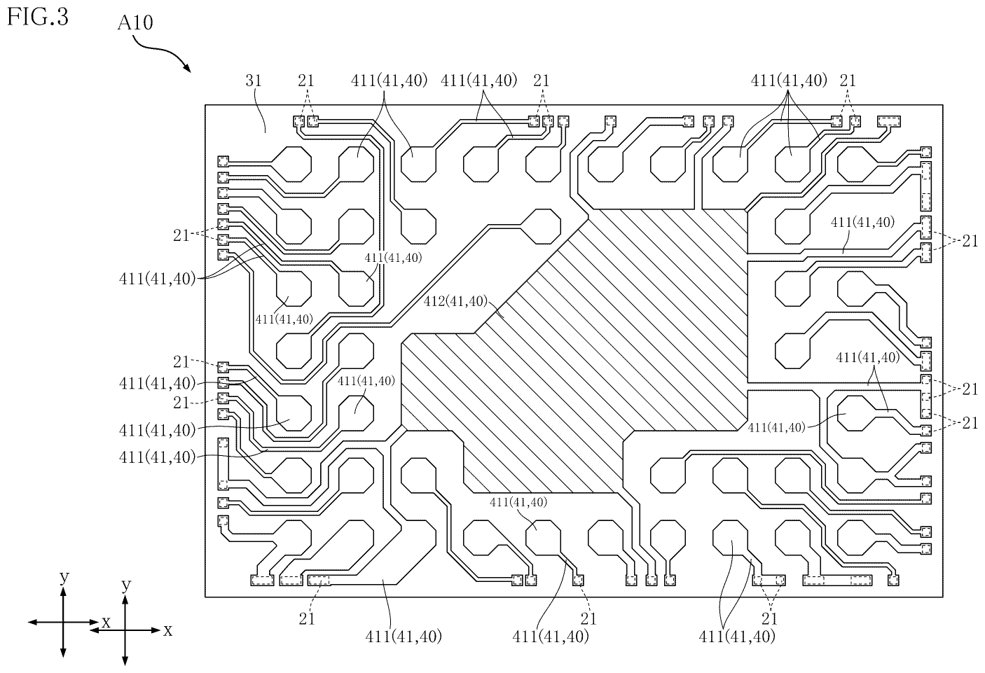

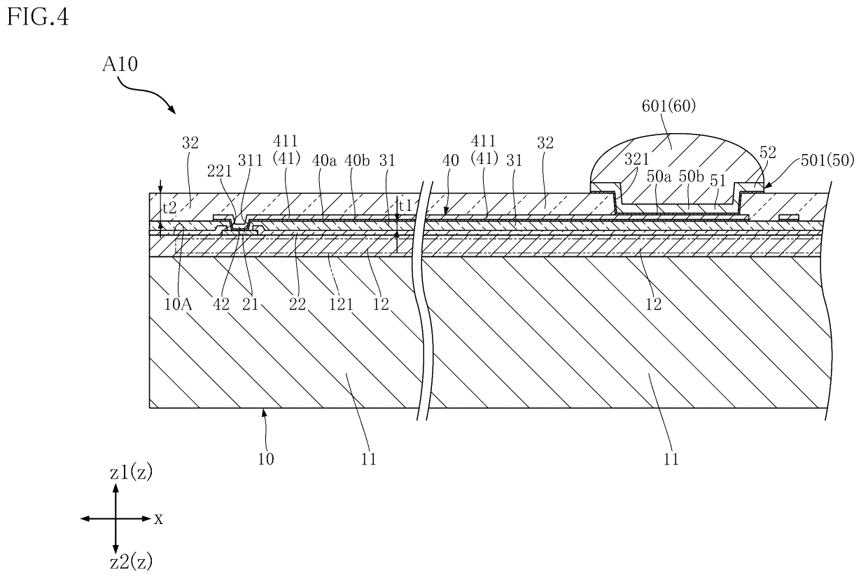

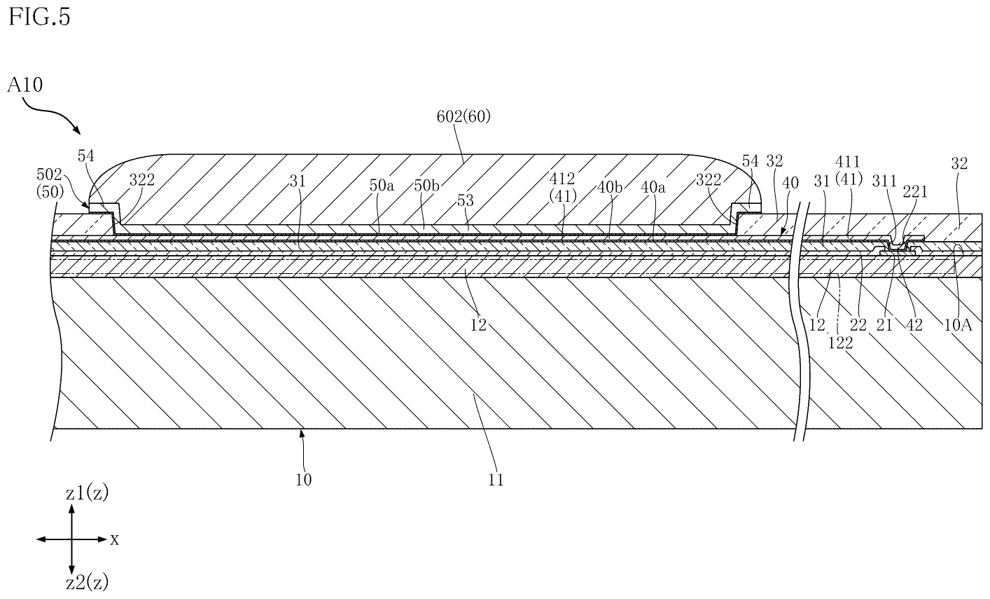

FIG. 1 is a plan view of the semiconductor device A10. FIG. 2 is a plan view of the semiconductor device A10, with the illustration of the terminals 50 and the conductive bonding layers 60 omitted. FIG. 3 is a plan view of the semiconductor device A10, with the illustration of the second insulating film 32 further omitted from FIG. 2. FIG. 4 is a partially enlarged sectional view taken along line IV-IV in FIG. 1. FIG. 5 is a partially enlarged sectional view taken along line V-V in FIG. 1.

As shown in FIGS. 4 and 5, the semiconductor element 10 includes a semiconductor substrate 11, and a semiconductor layer 12 located on the z1 side in the thickness direction z of the semiconductor substrate 11. The semiconductor element 10 has an obverse surface 10A facing the z1 side in the thickness direction z. The semiconductor layer 12 includes the obverse surface 10A. The semiconductor substrate 11 is formed from a silicon wafer, for example. Various semiconductor circuits, such as transistors and diodes, are formed on or near the obverse surface 10A of the semiconductor layer 12. In one example, the semiconductor layer 12 includes a first circuit 121 and a second circuit 122. The second circuit 122 may be a switching circuit, such as a metal-oxide-semiconductor field-effect transistor (MOSFET) or an insulated gate bipolar transistor (IGBT). The first circuit 121 is a control circuit for driving the second circuit 122. The second circuit 122 is driven by the first circuit 121. For example, the semiconductor element 10 is an LSI that includes the first circuit 121 and the second circuit 122 described above.

As shown in FIGS. 4 and 5, the electrodes 21 are located on the z1 side in the thickness direction z of the semiconductor element 10. The electrodes 21 are in contact with the obverse surface 10A (the surface facing the z1 side in the thickness direction z) of the semiconductor element 10. Each electrode 21 is electrically connected to a semiconductor circuit that is formed in the semiconductor layer 12. The electrodes 21 contain aluminum (Al), for example.

As shown in FIGS. 4 and 5, the passivation film 22 covers the obverse surface 10A of the semiconductor element 10 and a portion of each electrode 21. The passivation film 22 is a thin film containing silicon dioxide (SiO₂) or silicon nitride (Si₃N₄) or a stack of such thin films. The passivation film 22 has a plurality of openings 221. The openings 221 are each located above a corresponding electrode 21. The electrodes 21 are exposed through the respective openings 221 in the passivation film 22.

As shown in FIGS. 4 and 5, the first insulating film 31 is located between the semiconductor element 10 and the second insulating film 32 in the thickness direction z. The first insulating film 31 covers a portion of each electrode 21, and the passivation film 22. The first insulating film 31 is an insulator containing an organic compound. Examples of the organic compound include, but not limited to, polyimide. The first insulating film 31 includes portions located between the passivation film 22 and the re-wirings 40. As shown in FIGS. 4 and 5, the first insulating film 31 has a first opening(s) 311 extending through it in the thickness direction z. As viewed in the thickness direction z, the first opening 311 overlaps with one of the openings 221 in the passivation film 22. In the semiconductor device A10, the first opening 311 exposes one of the electrodes 21. In the illustrated example, the first opening 311 has an inclined inner surface relative to the thickness direction z. The cross-sectional area of the first opening 311 in a plane perpendicular to the thickness direction z gradually decreases from the z1 side to the z2 side in the thickness direction z.

As shown in FIGS. 4 and 5, the re-wirings 40 are located on the z1 side in the thickness direction z with respect to the electrodes 21. The re-wirings 40 are located between the plurality of electrodes 21 and the plurality of terminals 50 in the thickness direction z. Each re-wiring 40 is electrically connected to one of the electrodes 21.

Each re-wiring 40 includes a first base layer 40a and a first conductive layer 40b. The first base layer 40a includes a barrier layer in contact with one of the electrodes 21 and the first insulating film 31, and a seed layer stacked on the barrier layer. The barrier layer contains titanium (Ti). The seed layer contains copper (Cu). The first conductive layer 40b is stacked on the seed layer of the first base layer 40a. The first conductive layer 40b contains copper. The dimension of the first conductive layer 40b in the thickness direction z is greater than the dimension of the first base layer 40a in the thickness direction z.

As shown in FIGS. 4 and 5, each re-wiring 40 has a main portion 41 and a contact portion 42. The contact portion 42 is electrically connected to one of the electrodes 21. The contact portion 42 is in contact with the first insulating film 31 and is received within a first opening 311 in the first insulating film 31. As viewed in the thickness direction z, the entire contact portion 42 overlaps with one of the openings 221 in the passivation film 22. The main portion 41 is located on the opposite side of the contact portion 42 from the plurality of electrodes 21 in the thickness direction z. The contact portion 42 is connected to the main portion 41. The main portion 41 is located between the first insulating film 31 and the second insulating film 32.

As shown in FIGS. 3 to 5, the main portions 41 (the re-wirings 40) include a plurality of first re-wiring portions 411 and a second re-wiring portion 412. Each first re-wiring portion 411 is the wiring portion of that is electrically connected to a contact portion 42 and a terminal 50. Each first re-wiring portion 411 includes a portion that overlaps with one of the terminals 50 as viewed in the thickness direction z. The second re-wiring portion 412 is connected to a first re-wiring portion 411. The second re-wiring portion 412 is the wiring portion that overlaps with a plurality of terminals 50 as viewed in the thickness direction z. In FIG. 3, the second re-wiring portion 412 is shown with hatching. In the illustrated example, the second re-wiring portion 412 is disposed over a relatively large area as viewed in the thickness direction z. In the semiconductor device A10, one of the re-wirings 40 is composed both a first re-wiring portion 411 and the second re-wiring portion 412. The rest of the re-wirings 40 are composed solely of a first re-wiring portion 411 without the second re-wiring portion 412.

As shown in FIGS. 1, 3, and 4, each first re-wiring portion 411 (each re-wiring 40 composed solely of a first re-wiring portion 411) is electrically connected to the first circuit 121 of the semiconductor element 10 via an electrode 21. As shown in FIGS. 1, 3, and 5, the second re-wiring portion 412 is electrically connected to the second circuit 122 of the semiconductor element 10 via a first re-wiring portion 411 and an electrode 21.

As shown in FIGS. 4 and 5, the second insulating film 32 is located on the z1 side in the thickness direction z with respect to the first insulating film 31. The second insulating film 32 covers the first insulating film 31 and the re-wirings 40. The second insulating film 32 is an insulator containing an organic compound. The second insulating film 32 contains polyimide, for example. In the semiconductor device A10, the second insulating film 32 has the same composition as the first insulating film 31. The second insulating film 32 may contain polyamide, polybenzoxazole, or phenol resin, instead of polyimide.

The second insulating film 32 is in contact with the terminals 50. As shown in FIG. 4, a dimension t2 of the second insulating film 32 in the thickness direction z is greater than a dimension t1 of the first insulating film 31 in the thickness direction z. As shown in FIGS. 2, 4, and 5, the second insulating film 32 has a plurality of second openings 321 and a plurality of third openings 322 each extending through it in the thickness direction z. Each second opening 321 exposes the main portion 41 (a first re-wiring portion 411) of one of the re-wirings 40 (a re-wiring 40 that is composed solely of a first re-wiring portion 411). Each second opening 321 receives a portion of one of the terminals 50. Each second opening 321 exposes the main portion 41 (the second re-wiring portion 412) of one of the re-wirings 40 (the re-wiring 40 composed of both a first re-wiring portion 411 and the second re-wiring portion 412). As shown in FIGS. 2, 4, and 5, each third opening 322 has a larger area than each second opening 321 as viewed in the thickness direction z. In the illustrated example, the second openings 321 and the third openings 322 have respective inclined inner surfaces relative to the thickness direction z. The second openings 321 and the third openings 322 each have a cross-sectional area in a plane perpendicular to the thickness direction z that gradually decreases from the z1 side to the z2 side in the thickness direction z.

As shown in FIGS. 4 and 5, the terminals 50 are located on the opposite side of the semiconductor element 10 in the thickness direction z with respect to the electrodes 21 and the re-wirings 40. Each terminal 50 is electrically connected to the main portion 41 (the first re-wiring section 411 or the second re-wiring section 412) of one of the re-wirings 40. Thus, each terminal 50 is electrically connected to one of the electrodes 21. Each terminal 50 is located on the z1 side in the thickness direction z with respect to the re-wiring 40 that is connected to the terminal 50.

Each terminal 50 includes a second base layer 50a and a second conductive layer 50b. The second base layer 50a includes a barrier layer in contact with a corresponding re-wiring 40 (its main portion 41) and the second insulating film 32, and a seed layer stacked on the barrier layer. The barrier layer contains titanium, and the seed layer contains copper. The second conductive layer 50b is stacked on the seed layer of the second base layer 50a. The second conductive layer 50b contains copper. The dimension of the second conductive layer 50b in the thickness direction z is greater than the dimension of the second base layer 50a in the thickness direction z.

The plurality of terminals 50 include a plurality of first terminals 501 and a plurality of second terminals 502. As shown in FIG. 4, each first terminal 501 is connected to a first re-wiring portion 411. Each first terminal 501 is electrically connected to the first circuit 121 of the semiconductor element 10 via a first re-wiring portion 411 and an electrode 21. As shown in FIG. 5, each second terminal 502 is connected to the second re-wiring portion 412. Each second terminal 502 is electrically connected to the second circuit 122 of the semiconductor element 10 via the second re-wiring portion 412, a first re-wiring portion 411, and an electrode 21. As shown in FIGS. 1 and 5, in the present embodiment, the plurality of second terminals 502 (eight second terminals 502 in the example shown in FIG. 1) are connected to the second re-wiring portion 412.

As shown in FIGS. 1 and 5, the first terminals 501 are appropriately aligned along the first direction x and the second direction y as viewed in the thickness direction z. Each first terminal 501 is substantially circular as viewed in the thickness direction z.

As shown in FIG. 1, each second terminal 502 extends in the first direction x or the second direction y as viewed in the thickness direction z. As viewed in the thickness direction z, each second terminal 502 has a greater area than the first terminals 501. Each second terminal 502 extending in the first direction x has a length L2 in the first direction x that is at least twice the length L1 of the first terminals 501 in the first direction x. Each second terminal 502 that extends in the second direction y has a length L4 in the second direction y that is at least twice the length L3 of the first terminals 501 in the second direction y. In the illustrated example, the length L2 in the first direction x of each second terminal 502 extending in the first direction x is approximately 3.9 times the length L1 of the first terminals 501 in the first direction x. The length L4 in the second direction y of each second terminal 502 extending in the second direction y is approximately 2.4 to 3.9 times the length L3 of the first terminals 501 in the second direction y. Note, however, that the ratio of the length L2 of the second terminals 502 in the first direction x to the length L1 of the first terminals 501 in the first direction x is not limited to the above examples. Similarly, the ratio of the length L4 of the second terminals 502 in the second direction y to the length L3 of the first terminals 501 in the second direction y is not limited to the above examples.

As shown in FIG. 4, each first terminal 501 includes a first portion 51 and a second portion 52. The first portion 51 is received within a second opening 321 in the second insulating film 32. The second portion 52 is connected to the first portion 51 and protrudes beyond the second opening 321. As viewed in thickness direction z, the second portion 52 extends outside beyond the second opening 321.

As shown in FIG. 5, each second terminal 502 includes a third portion 53 and a fourth portion 54. The third portion 53 is received within a third opening 322 in the second insulating film 32. The fourth portion 54 is connected to the third portion 53 and protrudes beyond the third opening 322. As viewed in thickness direction z, the fourth portion 54 is located outside the third opening 322.

As shown in FIGS. 1, 3, and 4, the first terminals 501 are electrically connected to the first circuit 121 of the semiconductor element 10 each via a first re-wiring portion 411 (a re-wiring 40 solely composed of a first re-wiring portion 411) and an electrode 21. As shown in FIGS. 1, 3, and 5, the second terminals 502 are electrically connected to the second circuit 122 of the semiconductor element 10 each via the second re-wiring portion 412, a first re-wiring portion 411, and an electrode 21.

As shown in FIGS. 4 and 5, the conductive bonding layers 60 are located on the z1 side in the thickness direction z with respect to the plurality of terminals 50. The conductive bonding layers 60 are each electrically connected to a corresponding terminal 50. The conductive bonding layers 60 contain metal. The conductive bonding layers 60 is solder, for example. The conductive bonding layers 60 is made of a material containing tin (Sn). The melting point of the conductive bonding layers 60 is lower than that of the terminals 50. The upper surface (the surface facing in the z1 side in the thickness direction z) of each conductive bonding layer 60 is curved. Note, however, that the shape of the conductive bonding layers 60 is not limited to the illustrated example.

The plurality of conductive bonding layers 60 include a plurality of first conductive bonding layers 601 and a plurality of second conductive bonding layers 602. The first conductive bonding layers 601 are each electrically connected to a corresponding first terminal 501. The second conductive bonding layers 602 are each electrically connected to a corresponding second terminal 502. Each first conductive bonding layer 601 overlaps with the entirety of the corresponding first terminal 501. Each second conductive bonding layer 602 overlaps with the entirety of the corresponding second terminal 502. As shown in FIGS. 1 and 4, the plurality of first conductive bonding layers 601 are substantially circular as viewed in the thickness direction z, and their shape and size substantially match those of the first terminals 501. As shown in FIGS. 1 and 5, each second conductive bonding layer 602 has the shape and size substantially matching those of the corresponding second terminal 502 as viewed in the thickness direction z.

As shown in FIG. 1, each second conductive bonding layer 602 extends in the first direction x or the second direction y as viewed in the thickness direction z. As viewed in the thickness direction z, each second conductive bonding layer 602 has a greater area than the first conductive bonding layers 601. Each second conductive bonding layer 602 extending in the first direction x has a length L2 in the first direction x that is at least twice the length L1 of the first conductive bonding layers 601 in the first direction x. Each conductive bonding layers 602 extending in the second direction y has a length L4 in the second direction y that is at least twice the length L3 of the first conductive bonding layers 601 in the second direction y. In the illustrated example, the length L2 in the first direction x of each second conductive bonding layer 602 extending in the first direction x is approximately 3.9 times the length L1 of the first conductive bonding layers 601 in the first direction x. The length L4 in the second direction y of each second conductive bonding layer 602 extending in the second direction y is approximately 2.4 to 3.9 times the length L3 of the first conductive bonding layers 601 in the second direction y. Note, however, that the ratio of the length L2 of the second conductive bonding layers 602 in the first direction x to the length L1 of the first conductive bonding layers 601 in the first direction x is not limited to the above examples. Similarly, the ratio of the length L4 of the second conductive bonding layers 602 in the second direction y to the length L3 of the first conductive bonding layers 601 in the second direction y is not limited to the above examples.

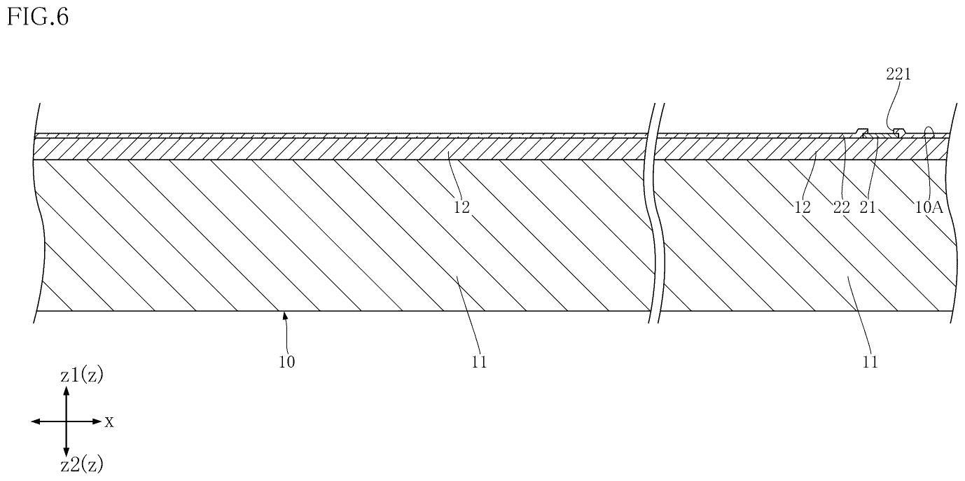

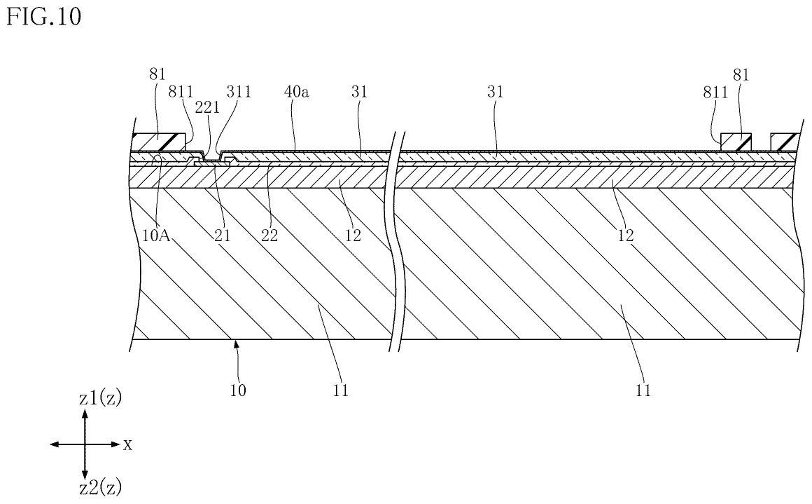

With reference to FIGS. 6 to 26, the following describes an example of a method for manufacturing a semiconductor device A10. FIGS. 6 to 26 are enlarged sectional views, each illustrating a step of the method for manufacturing a semiconductor device A10. FIGS. 6 to 9, 11 to 13, 15, 17, 19, 21, 23, and 25 each show a sectional view corresponding to the sectional view shown in FIG. 5. FIGS. 10, 14, 16, 18, 20, 22, 24, and 26 each show a sectional view corresponding FIG. 4.

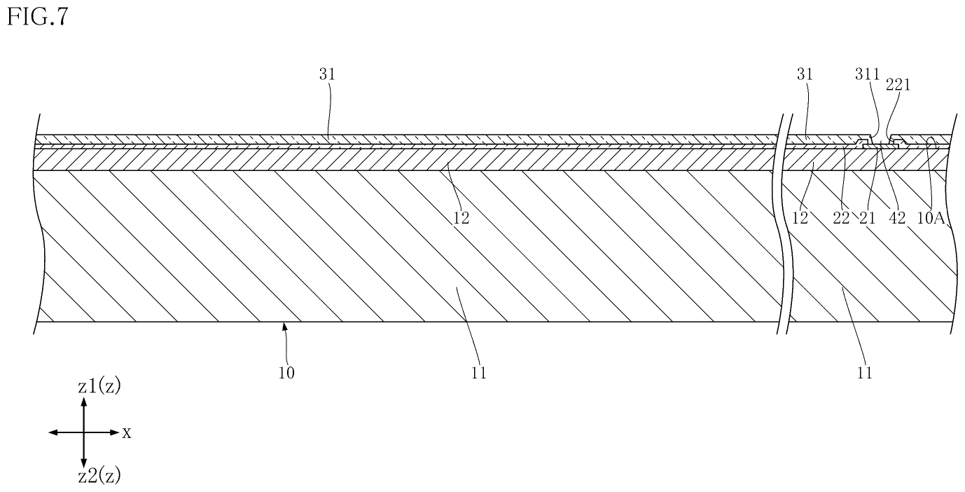

First, a semiconductor element 10 is prepared as shown in FIG. 6. The semiconductor element 10 at this stage is part of a silicon wafer. The semiconductor element 10 is provided with a plurality of electrodes 21 and a passivation film 22 on the z1 side in the thickness direction z. Subsequently, a first insulating film 31 is formed on the z1 side of the semiconductor element 10 in the thickness direction z as shown in FIG. 7. The process of forming the first insulating film 31 involves applying photosensitive polyimide to the passivation film 22 using, for example, spin coating, followed by lithographic patterning and hardening. As a result of the lithographic patterning, a plurality of first openings 311 are formed in the first insulating film 31. Each first opening 311 exposes a portion of an electrode 21. Note that the process for forming the first insulating film 31 can be changed as necessary, depending on the material used for the first insulating film 31. Note, in addition, that the first opening 311 shown in the figures is inclined (or has an inner surface inclined) relative to the thickness direction z, but the shape of the first openings 311 is not limited to this. For example, depending on the process of forming the first openings 311, each first opening 311 may be formed in a shape that extends along the thickness direction z without inclination in the thickness direction z.

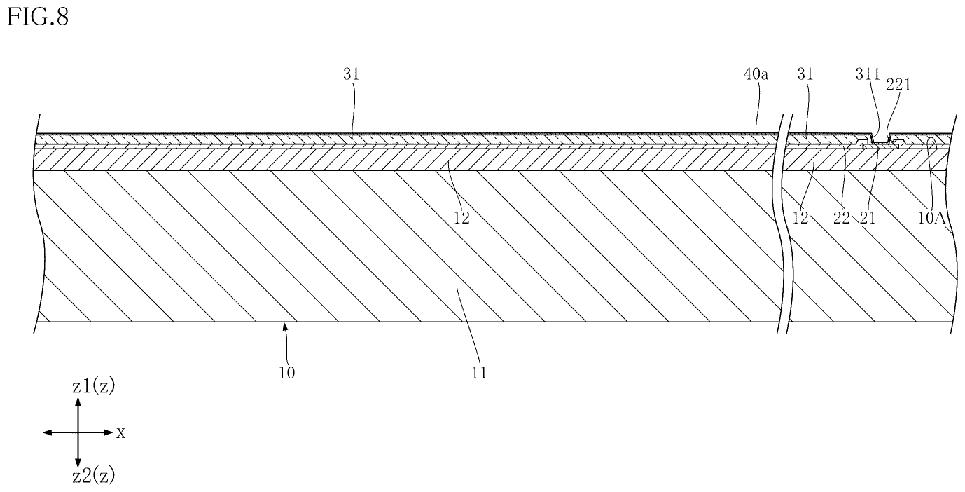

Subsequently, a first base layer 40a is formed as shown in FIG. 8. The first base layer 40a may be formed using spin coating. However, the method for forming the first base layer 40a is not limited to this. For example, sputtering may be used. In this step, the first base layer 40a is formed to cover the entire first insulating film 31, as well as the portions of the passivation film 22 and the electrodes 21 that are exposed through the first openings 311 in the first insulating film 31. In other words, the in-process semiconductor device A10 shown in FIG. 7 has an upper surface (the surface facing the z1 side in the thickness direction z) that is entirely covered with the first base layer 40a. The process of forming the first base layer 40a may involve forming a barrier layer containing titanium, for example, and then forming a seed layer containing copper.

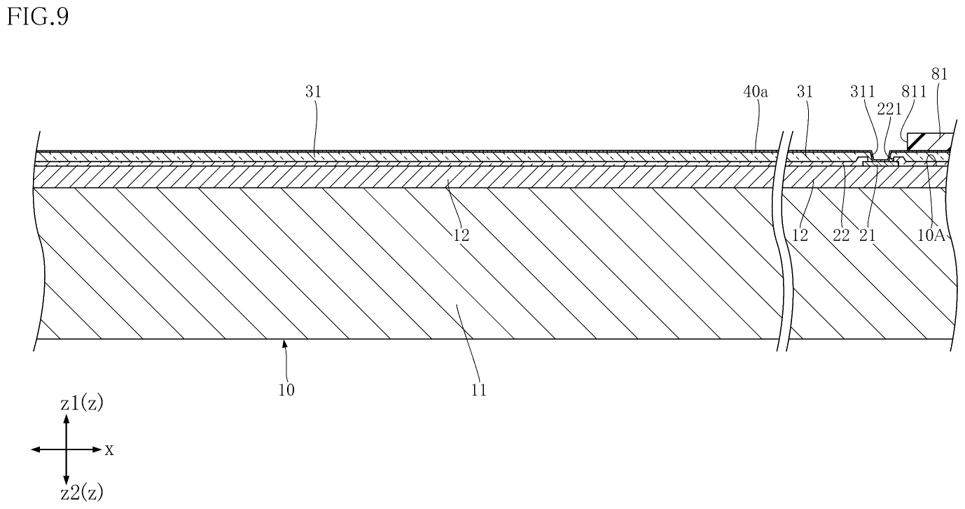

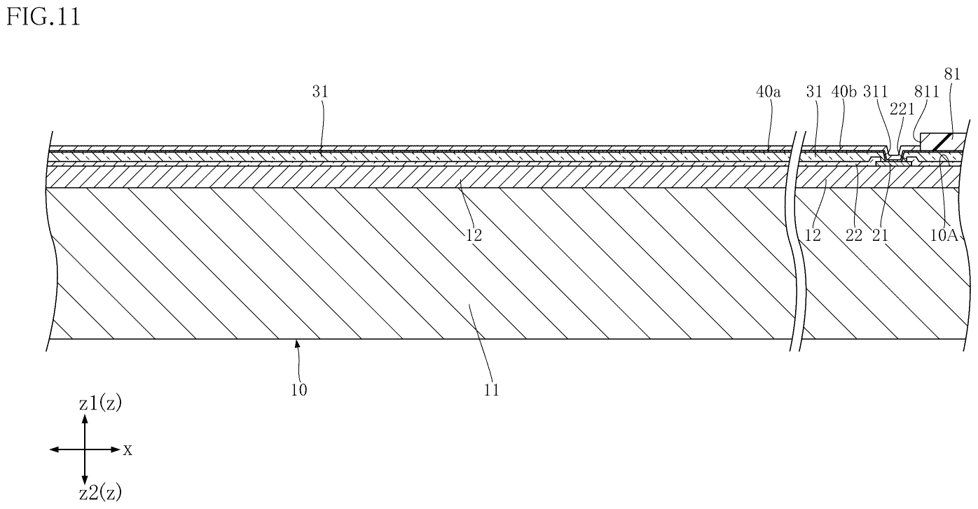

Subsequently, a first conductive layer 40b is formed as shown in FIGS. 9 to 11. To form the first conductive layer 40b, a first resist 81 is applied to the first base layer 40a and then patterned using lithography as shown in FIGS. 9 and 10. As a result, a plurality of openings 811 are formed through the first resist 81 in the thickness direction z. Subsequently, electroplating is performed using the first base layer 40a as the conduction path, depositing the first conductive layer 40b as shown in FIG. 11. The first conductive layer 40b contains copper, for example. Through the above, a plurality of first conductive layer 40b are formed within the openings 811.

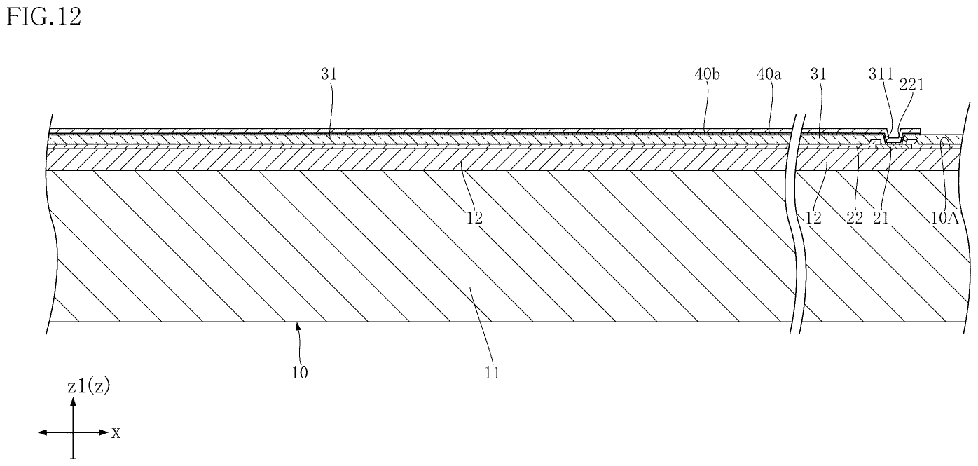

Subsequently, as shown in FIG. 12, the first resist 81 is removed, and then the portions of the first base layer 40a that are not covered with the first conductive layer 40b are removed. The removal of the first base layer 40a may be performed using wet etching with a mixed solution of sulfuric acid (H₂SO₄) and hydrogen peroxide (H₂O₂), for example. As shown in FIG. 12, each first conductive layer 40b is partly located inside the first opening 311, partly on the first insulating film 31, and partly on the electrode 21. Through the above, the re-wirings 40 are formed.

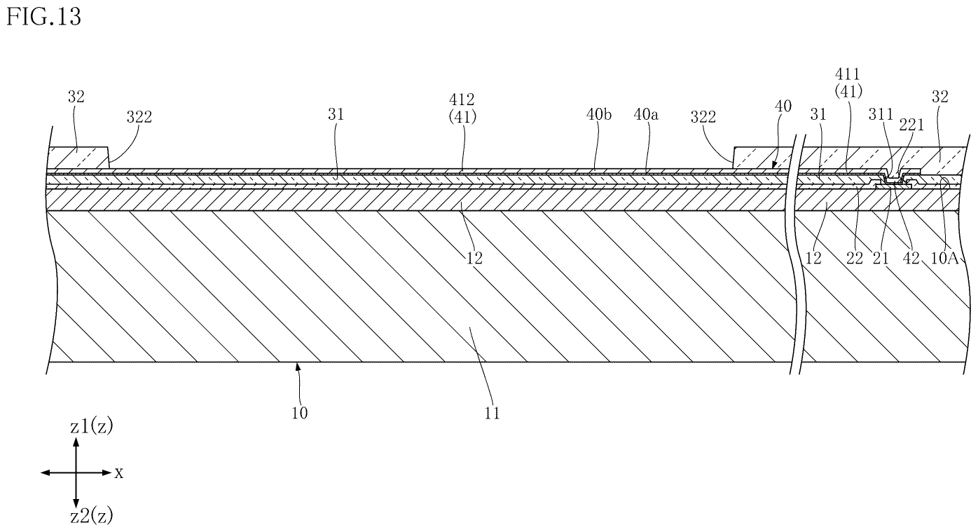

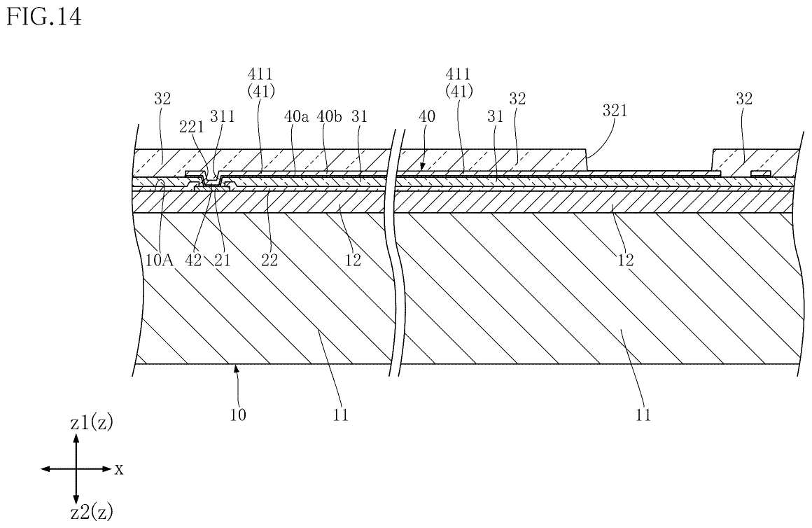

Subsequently, a second insulating film 32 is formed as shown in FIGS. 13 and 14. To form the second insulating film 32, a material containing photosensitive polyimide is applied to the re-wirings 40 and the portion of the first insulating film 31 that is not covered with the re-wirings 40, followed by lithographic patterning and hardening. As a result of the lithographic patterning, a plurality of second openings 321 and a plurality of third openings 322 are formed in the second insulating film 32. As viewed in the thickness direction z, each third opening 322 has a larger area than each second opening 321. Each second opening 321 exposes a portion of a re-wiring 40 (a portion of a first re-wiring portion 411) as shown in FIG. 14. Each third opening 322 exposes a portion of a re-wiring 40 (a portion of the second re-wiring portion 412) as shown in FIG. 13. Note that the process for forming the second insulating film 32 can be changed as necessary, depending on the material used for the second insulating film 32. In addition, although the figures show that the second openings 321 and the third openings 322 are inclined relative to the thickness direction z, this is a non-limiting example. For example, depending on the process used for forming the second openings 321 and the third openings 322, each second opening 321 and third opening 322 may be formed in a shape that extends along the thickness direction z without inclination.

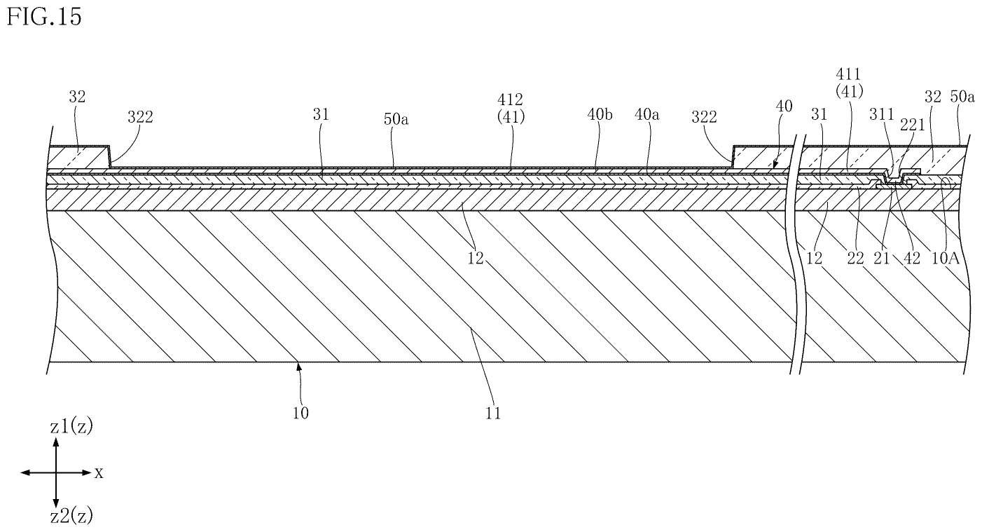

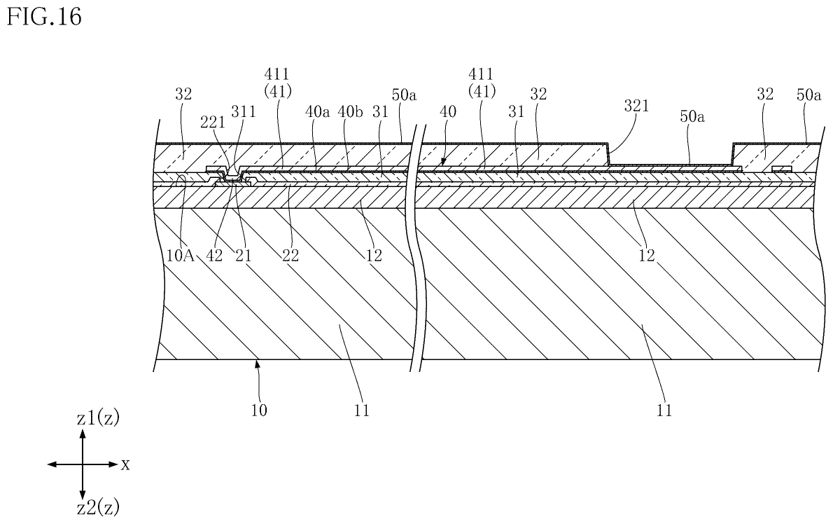

Subsequently, a second base layer 50a is formed as shown in FIGS. 15 and 16. The second base layer 50a may be formed using sputtering, but this is a non-limiting example. In this step, the second base layer 50a is formed to cover the entire second insulating film 32, as well as the portions of the re-wirings 40 (the portions of the first re-wiring portions 411 and of the second re-wiring portion 412) that are exposed through the second openings 321 and the third openings 322 in the second insulating film 32. In other words, the in-process semiconductor device A10 shown in FIGS. 13 and 14 has an upper surface (the surface facing the z1 side in the thickness direction z) that is entirely covered with the second base layer 50a. The process of forming the second base layer 50a may involve forming a barrier layer containing titanium, for example, and then forming a seed layer containing copper.

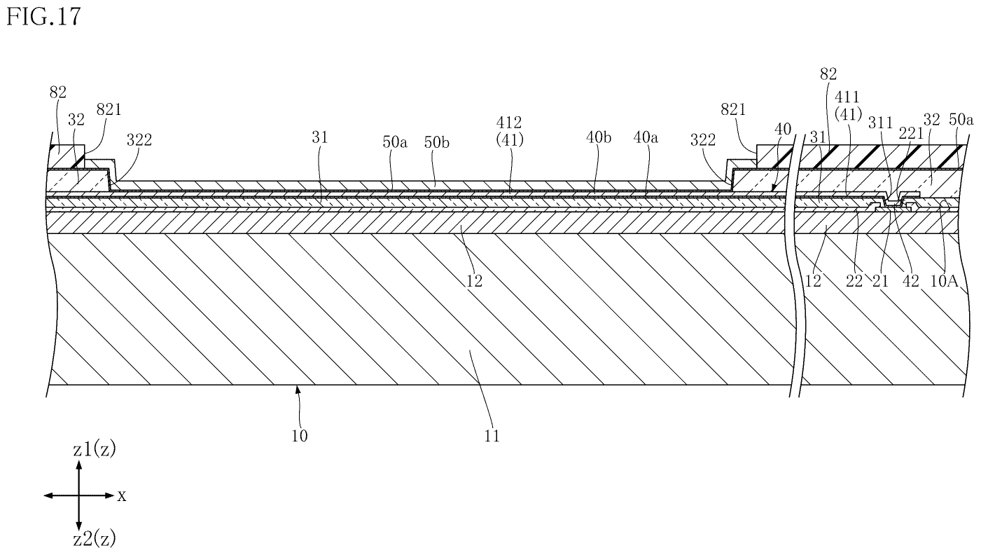

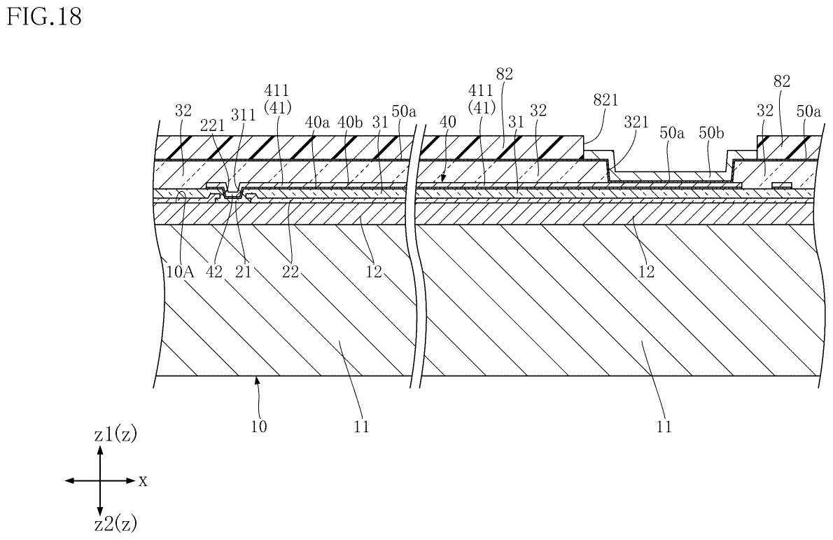

Subsequently, a second conductive layer 50b is formed as shown in FIGS. 17 to 20. To form the second conductive layer 50b, a second resist 82 is applied to the second base layer 50a and is then patterned using lithography as shown in FIGS. 17 and 18. As a result, a plurality of openings 821 are formed through the second resist 82 in the thickness direction z. Subsequently, electroplating is performed using the second base layer 50a as the conduction path, depositing the second conductive layer 50b. The second conductive layer 50b contains copper, for example. Through the above, a plurality of second conductive layers 50b are formed within the openings 821.

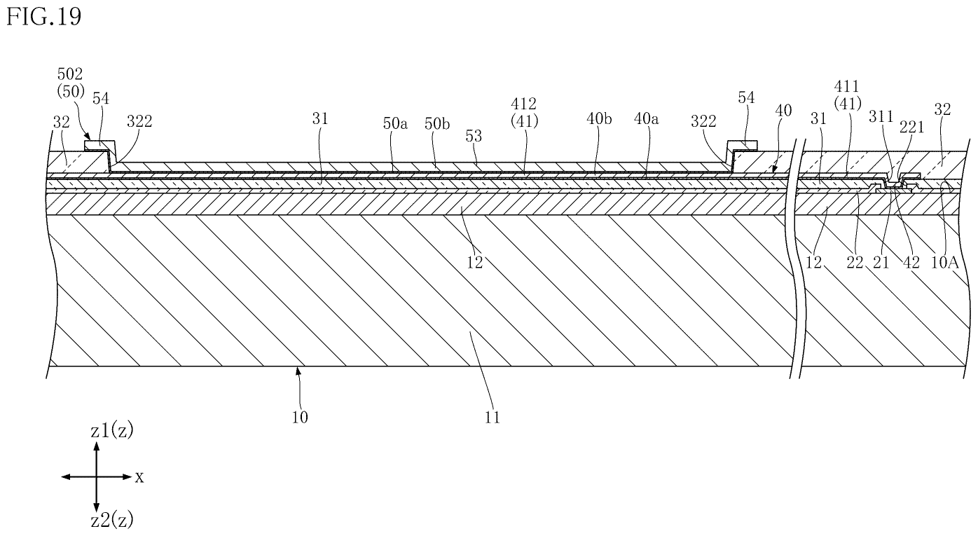

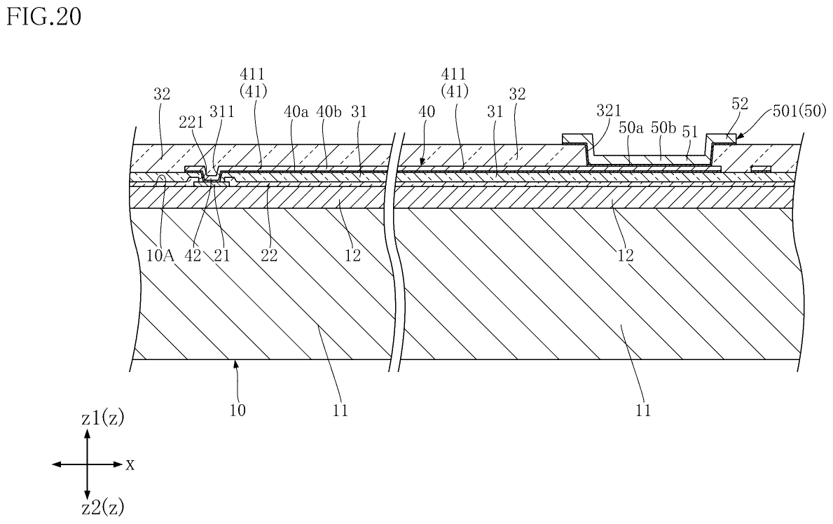

Subsequently, as shown in FIGS. 19 and 20, the second resist 82 is removed, and then the portions of the second base layer 50a that are not covered with the second conductive layer 50b are removed. The removal of the second base layer 50a may be performed using wet etching with a mixed solution of sulfuric acid and hydrogen peroxide, for example. Through the above, a plurality of terminals 50 (a plurality of first terminals 501 and a plurality of second terminals 502) are formed.

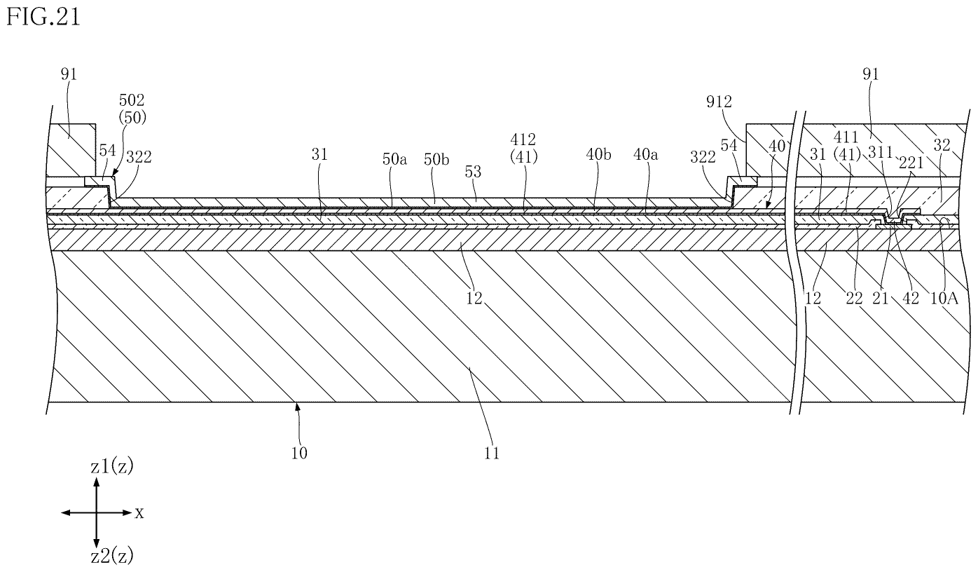

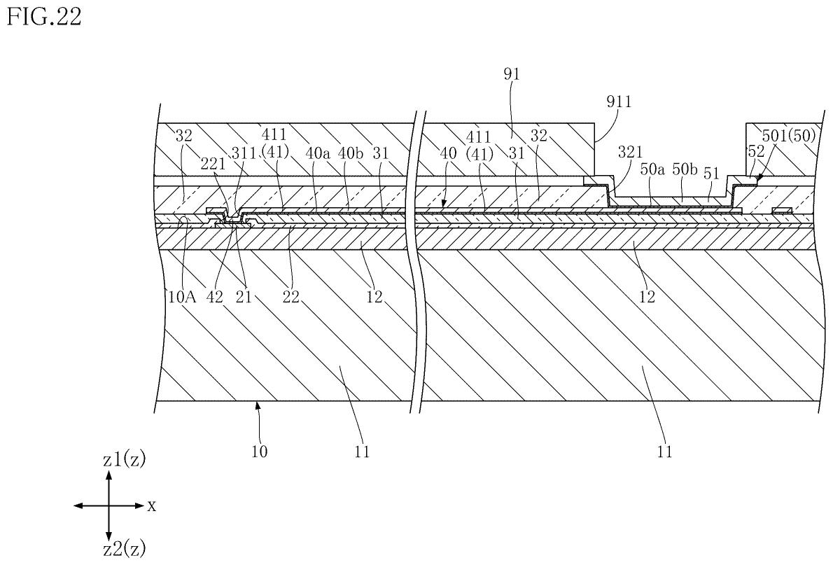

Subsequently, a plurality of conductive bonding layers 60 are formed. To form the conductive bonding layers 60, a screen 91 is placed over the terminals 50 from the z1 side in the thickness direction z as shown in FIGS. 21 and 22. The screen 91 is a metal plate (a metal mask) formed with a plurality of slits 911 and a plurality of slits 912 each extending through it in the thickness direction z. The slits 911 have the shape and size matching those of the first terminals 501 as viewed in the thickness direction z. The slits 912 have the shape and size matching those of the second terminals 502 as viewed in the thickness direction z.

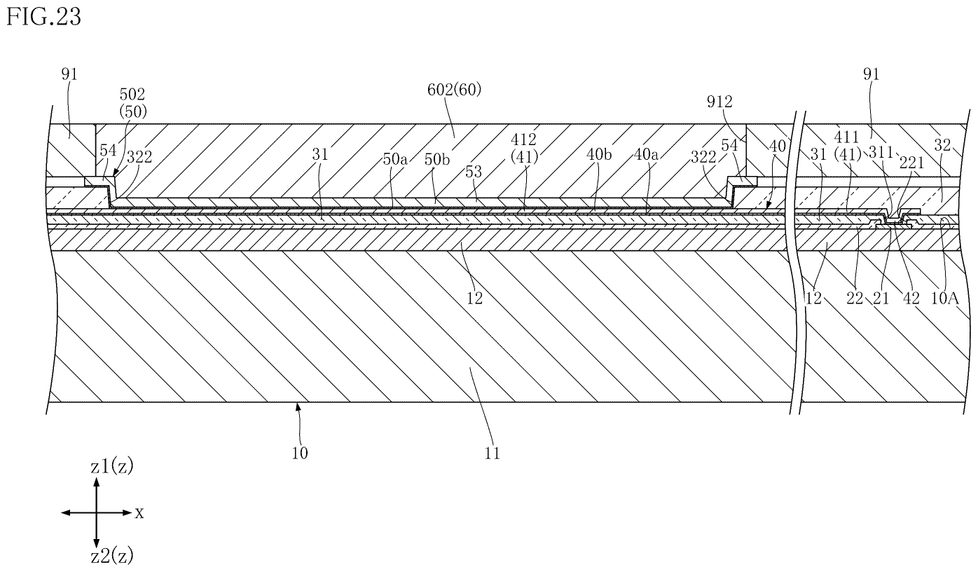

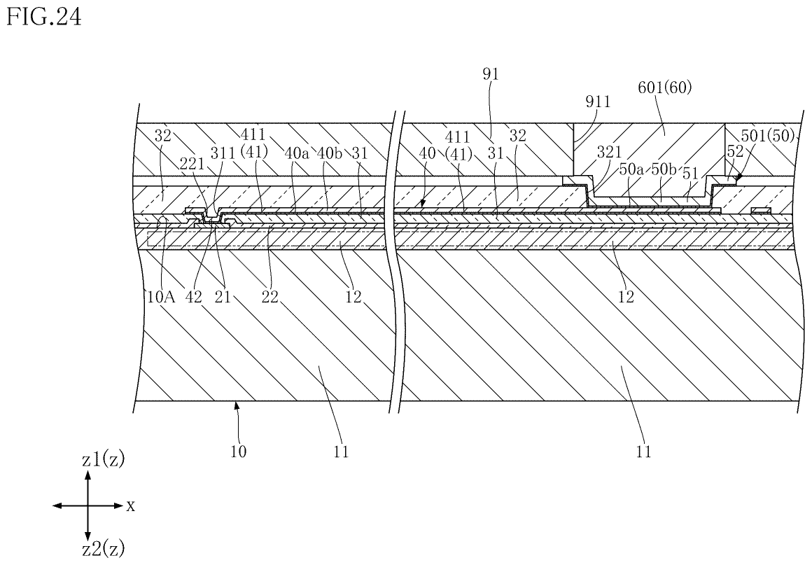

Subsequently, as shown in FIGS. 23 and 24, a material containing solder (the conductive bonding layers 60) is deposited onto the terminals 50 by screen printing. As a result, the first conductive bonding layers 601 are deposited exclusively at the positions where the material passes through the slits 911 above the first terminals 501. Similarly, the second conductive bonding layer 602 are deposited exclusively at the positions where the material passes through the slits 912 above the second terminals 502. The screen 91 is then removed. The first conductive bonding layers 601 and the second conductive bonding layers 602 thus deposited are aligned in height at their ends on the z1 side in the thickness direction z. The term “screen printing” used herein includes both the process involving the use of a metal mask and the process involving the use of a mesh screen.

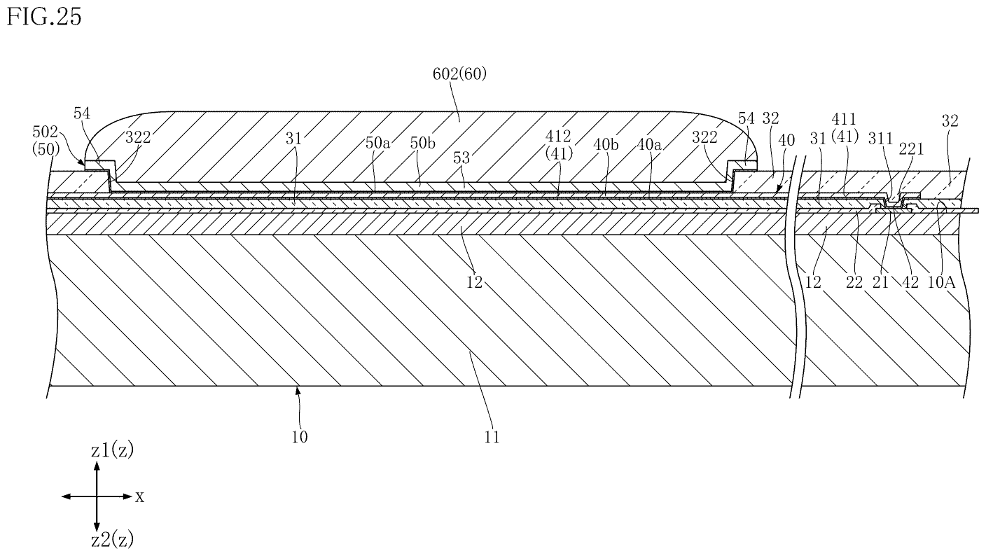

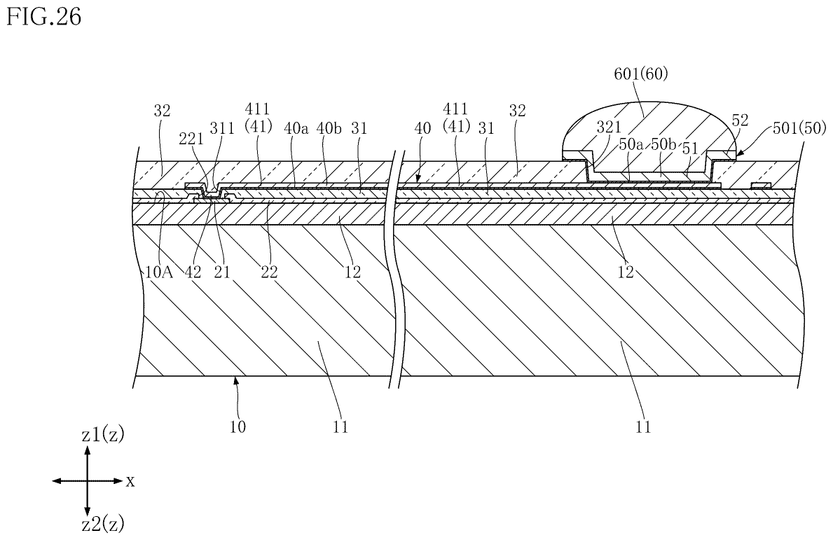

Subsequently, the conductive bonding layers 60 (the first conductive bonding layers 601 and the second conductive bonding layers 602), which are made of the material containing solder, is caused to melt by reflowing. Then, the molten material is allowed to harden. Through the above, the plurality of conductive bonding layers 60 (the first conductive bonding layers 601 and the second conductive bonding layers 602) are formed on the respective terminals 50 (the first terminals 501 and the second terminals 502) as shown in FIGS. 25 and 26.

Finally, the semiconductor element 10, which at this stage is still part of a silicon wafer, is separated into an individual chip using blade dicing. Through the steps described above, the semiconductor device A10 is manufactured. Note, however, that the method for manufacturing the semiconductor device A10 described above is a non-limiting example.

To prepare for use, the semiconductor device A10 is surface-mounted on a circuit board (not illustrated), for example. The terminals 50 of the semiconductor device A10 are electrically bonded to the conductive parts of the circuit board individually via the conductive bonding layers 60. As a result, the electrodes 21 of the semiconductor device A10 are electrically connected to the conductive parts of the circuit board.

The following describes the effects of the semiconductor device A10.

A semiconductor device A10 includes a semiconductor element 10, an electrode 21, a re-wiring 40, a terminal 50, and a conductive bonding layer 60. The electrode 21 is located on the z1 side in the thickness direction z of the semiconductor element 10. The re-wiring 40 is located on the z1 side in the thickness direction z with respect to the electrode 21 and is electrically connected to the electrode 21. The terminal 50 is located on the z1 side in the thickness direction z with respect to the re-wiring 40 and is electrically connected to the re-wiring 40. The terminal 50 and the conductive bonding layer 60 together form a conduction path connecting the semiconductor element 10 and a circuit board, for example, on which the semiconductor device A10 is mounted. The terminal 50 includes a first terminal 501 and a second terminal 502, and the conductive bonding layer 60 includes a first conductive bonding layer 601 and a second conductive bonding layer 602. As viewed in the thickness direction z, the second terminal 502 has a greater area than the first terminal 501. Similarly, as viewed in the thickness direction z, the second conductive bonding layer 602 has a greater area than the first conductive bonding layer 601. This configuration ensures, for the terminal 50 forming a conduction path connecting the semiconductor element 10 to an external component (e.g., a circuit board), that the second terminal 502 has lower resistance than the first terminal 501. This configuration also ensures that the second conductive bonding layer 602 forming the conduction path has lower resistance than the first conductive bonding layers 601. The semiconductor device A10 therefore achieves reduced resistance even when a large electric current is fed to the semiconductor device A10.

The second terminal 502 and the second conductive bonding layer 602 extend in the first direction x perpendicular to the thickness direction z. The second terminal 502 extending in the first direction x has a length L2 in the first direction x that is at least twice the length L1 of the first terminal 501 in the first direction x. The length L2 of the second conductive bonding layer 602 in the first direction x is at least twice the length L1 of the first conductive bonding layer 601 in the first direction x. This configuration ensures that the second terminal 502 and the second conductive bonding layer 602 have lower resistance compared to the first terminal 501 and the first conductive bonding layer 601.

The semiconductor element 10 includes a first circuit 121 and a second circuit 122. The first terminal 501 is electrically connected to the first circuit 121, and the second terminal 502 is electrically connected to the second circuit 122. The second circuit 122 is driven by the first circuit 121. The second circuit 122 may be a switching circuit. Thus, the second terminal 502 and the second conductive bonding layer 602, which are electrically connected to the second circuit 122, may conduct a large electric current. The configuration described above effectively reduces the resistance of the second terminal 502 and the second conductive bonding layer 602, which may conduct a large electric current.

The manufacture of the semiconductor device A10 includes a step of forming a conductive bonding layer 60 by screen printing. This configuration ensures that the first conductive bonding layer 601 and the second conductive bonding layer 602, which have different areas as viewed in the thickness direction z, are aligned in height (at the ends on the z1 side in the thickness direction z). This improves the reliability with which the semiconductor device A10 is attached to a circuit board or the like through the conductive bonding layers 60 (the first conductive bonding layers 601 and the second conductive bonding layers 602).

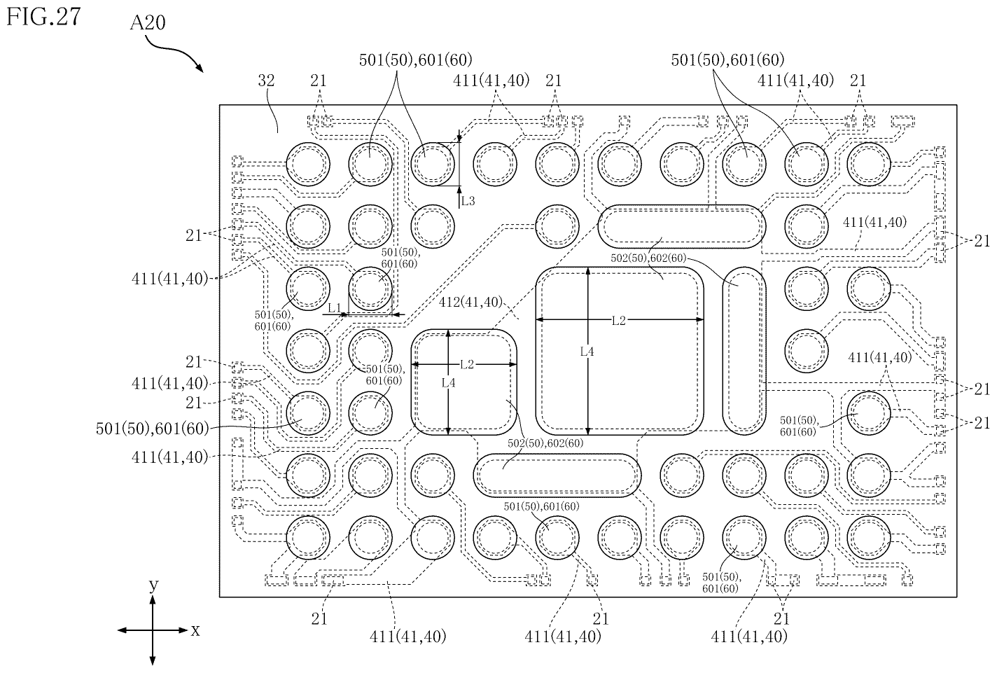

FIGS. 27 to 30 show semiconductor devices according to other embodiments of the present disclosure. In these figures, elements that are identical or similar to those of the embodiment described above are indicated by the same reference numerals, and redundant descriptions are omitted. In addition, configurations of elements and components in the embodiments may be combined in any manner, provided that no technical inconsistencies arise.

### Second Embodiment

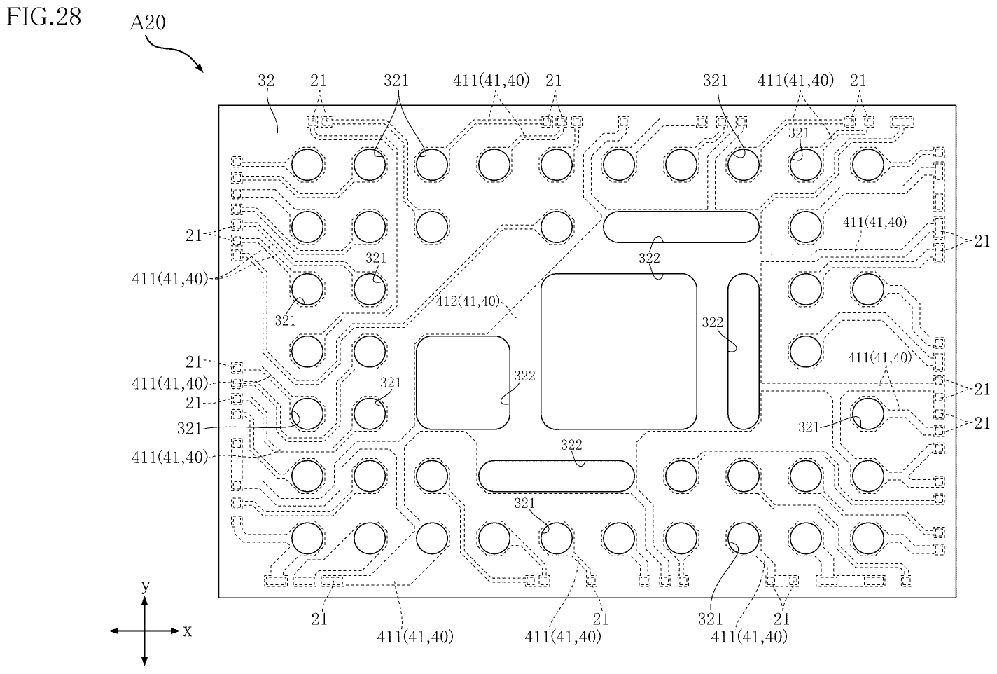

FIGS. 27 and 28 show a semiconductor device A20 according to a second embodiment of the present disclosure. FIG. 27 is a plan view of the semiconductor device A20. FIG. 28 is a plan view of the semiconductor device A20, with the illustration of the terminals 50 and the conductive bonding layers 60 omitted.

In the semiconductor device A20, the second terminals 502 and the second conductive bonding layers 602 include those having a greater area than those of the semiconductor device A10 of the above embodiment as viewed in the thickness direction z. As viewed in the thickness direction z, the second terminals 502 and the second conductive bonding layers 602 that are located near the center of the semiconductor device A20 in the first direction x and the second direction y have a rectangular shape extending in the first direction x and the second direction y. These second terminals 502 and second conductive bonding layers 602 have a length L2 in the first direction x that is at least twice the length L1 of the first terminals 501 and the first conductive bonding layers 601 in the first direction x, and a length L4 in the second direction y that is at least twice the length L3 of the first terminals 501 and the first conductive bonding layers 601 in the second direction y. In the illustrated example, the length L2 in the first direction x of the second terminals 502 and second conductive bonding layers 602 that are located near the center in the first direction x and the second direction y is approximately 2.4 to 3.9 times the length L1 of the first terminals 501 and the first conductive bonding layers 601 in the first direction x. Similarly, the length L4 in the second direction y of these second terminals 502 and second conductive bonding layers 602 is approximately 2.4 to 3.9 times the length L3 of the first terminals 501 and the first conductive bonding layers 601 in the second direction y.

In the semiconductor device A20, each second terminals 502 has a greater area than the first terminals 501 as viewed in the thickness direction z. In addition, each second conductive bonding layer 602 has a greater area than the first conductive bonding layers 601 as viewed in the thickness direction z. This configuration ensures, for the terminals 50 forming a conduction path connecting the semiconductor element 10 to an external component (e.g., a circuit board), that the second terminals 502 have lower resistance than the first terminals 501. This configuration also ensures that the second conductive bonding layers 602 forming the conduction path have lower resistance than the first conductive bonding layers 601. The semiconductor device A20 therefore achieves reduced resistance even when a large electric current is fed to the semiconductor device A20.

In the semiconductor device A20, the second terminals 502 and the second conductive bonding layers 602 include those having a greater area as viewed in the thickness direction z. Specifically, those second terminals 502 and second conductive bonding layers 602 of the semiconductor device A20 each have a length L2 in the first direction x that is at least twice the length L1 of the first terminals 501 and the first conductive bonding layers 601 in the first direction x, and a length L4 in the second direction y that is at least twice the length L3 of the first terminals 501 and the first conductive bonding layers 601 in the second direction y. The configuration described above effectively reduces the resistance of the second terminals 502 and the second conductive bonding layers 602. Additionally, the semiconductor device A20 has a configuration in common with the semiconductor device A10, thereby achieving the same effect as the semiconductor device A10.

### Third Embodiment

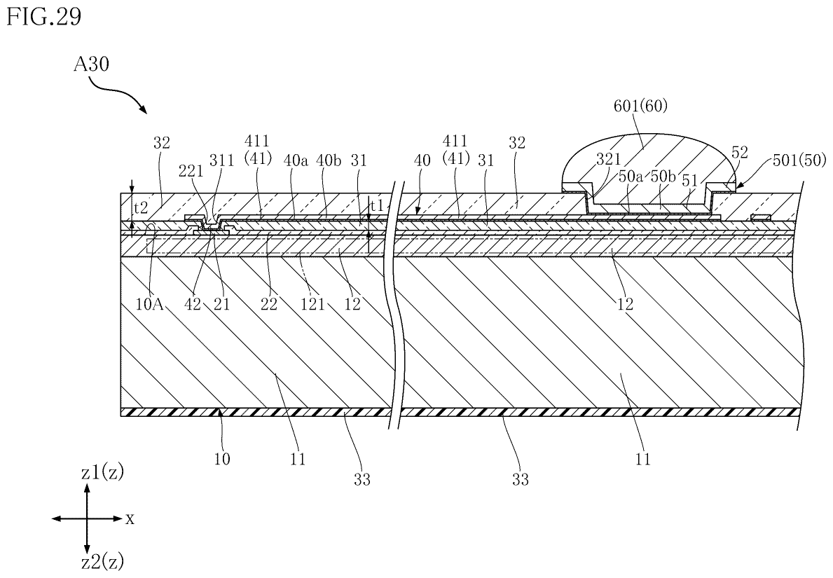

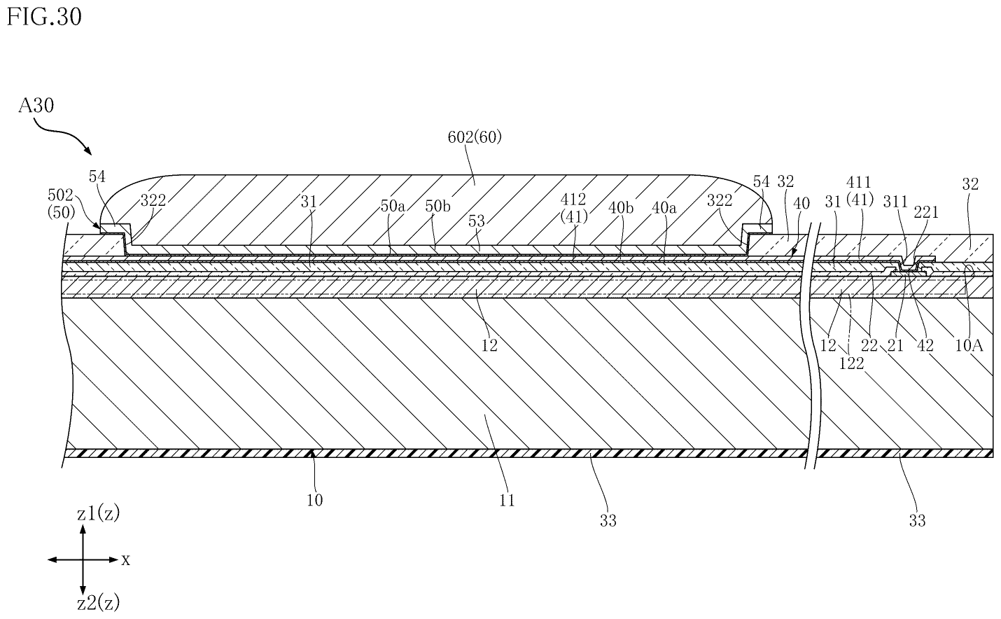

FIGS. 29 and 30 show a semiconductor device A30 according to a third embodiment of the present disclosure. FIGS. 29 and 30 are each partially enlarged sectional view of the semiconductor device A30. FIG. 29 shows a sectional view corresponding to FIG. 4, and FIG. 30 to FIG. 5.

The semiconductor device A30 differs from the semiconductor device A10 by the addition of a third insulating film 33.

The third insulating film 33 is located on the opposite side of the semiconductor element 10 from the plurality of electrodes 21 in the thickness direction z. The third insulating film 33 covers the semiconductor element 10 from the z2 side of in the thickness direction z. The third insulating film 33 is made of an insulating resin sheet, for example.

In the semiconductor device A30, each second terminal 502 has a greater area than the first terminals 501 as viewed in the thickness direction z. In addition, each second conductive bonding layer 602 has a greater area than the first conductive bonding layers 601 as viewed in the thickness direction z. This configuration ensures, for the terminals 50 forming a conduction path connecting the semiconductor element 10 to an external component (e.g., a circuit board), that the second terminals 502 have lower resistance than the first terminals 501. This configuration also ensures that the second conductive bonding layers 602 forming the conduction path have lower resistance than the first conductive bonding layers 601. The semiconductor device A30 therefore achieves reduced resistance even when a large electric current is fed to the semiconductor device A30.

The semiconductor device A30 additionally includes the third insulating film 33. The third insulating film 33 covers the semiconductor element 10 from the z2 side in the thickness direction z. The third insulating film 33 appropriately protects the semiconductor element 10 (the semiconductor device A30). Additionally, the semiconductor device A30 has a configuration in common with the semiconductor device A10, thereby achieving the same effect as the semiconductor device A10.

The semiconductor devices according to the present disclosure are not limited to the embodiments described above. The specific configuration of each part of a semiconductor device according to the present disclosure may suitably be designed and changed in various manners. Although the embodiments described above are directed to the semiconductor devices A10 to A30 each formed using WL-CSP, the present disclosure is not limited to these. For example, the semiconductor devices according to the present disclosure may be resin packaged devices that is sealed with mold resin.

The present disclosure includes the configurations described in the following clauses.

Clause 1.

A semiconductor device (A10) comprising:
a semiconductor element (10);
an electrode (21) located on a first side (z1 side) in a thickness direction of the semiconductor element (10);
a re-wiring (40) located on the first side (z1 side) in the thickness direction (z) with respect to the electrode (21) and electrically connected to the electrode (21);
a terminal (50) located on the first side (z1 side) in the thickness direction (z) with respect to the re-wiring (40) and electrically connected to the re-wiring (40); and
a conductive bonding layer (60) located on the first side (z1 side) in the thickness direction (z) with respect to the terminal (50) and electrically connected to the terminal (50),
wherein the terminal (50) includes a first terminal (501) and a second terminal (502),
the conductive bonding layer (60) includes a first conductive bonding layer (601) electrically connected to the first terminal (501), and a second conductive bonding layer (602) electrically connected to the second terminal (502),
as viewed in the thickness direction (z), an area of the second terminal (502) is greater than an area of the first terminal (501), and
as viewed in the thickness direction (z), an area of the second conductive bonding layer (602) is greater than an area of the first conductive bonding layer (601).

Clause 2.

The semiconductor device (A10) according to Clause 1, wherein as viewed in the thickness direction (z), the second conductive bonding layer (602) overlaps with an entirety of the second terminal (502).

Clause 3.

The semiconductor device (A10) according to Clause 1 or 2, wherein the second terminal (502) and the second conductive bonding layer (602) extend in a first direction (x) perpendicular to the thickness direction (z), a length of the second terminal (502) in the first direction (x) is at least twice a length of the first terminal (501) in the first direction (x), and a length of the second conductive bonding layer (602) in the first direction (x) is at least twice a length of the first conductive bonding layer (601) in the first direction (x).

Clause 4.

The semiconductor device (A20) according to Clause 1 or 2, wherein a length of the second terminal (502) in a first direction (x) perpendicular to the thickness direction (z) is at least twice a length of the first terminal in the first direction (x), and
a length of the second terminal (502) in a second direction (y) perpendicular to the thickness direction and the first direction (x) is at least twice a length of the first terminal (501) in the second direction (y),
a length of the second conductive bonding layer (602) in the first direction (x) is at least twice a length of the first conductive bonding layer (601) in the first direction (x), and
a length of the second conductive bonding layer (602) in the second direction (y) is at least twice a length of the first conductive bonding layer (601) in the second direction (y).

Clause 5.

The semiconductor device (A10) according to any one of Clauses 1 to 4, wherein the conductive bonding layer (60) is made of a material containing tin.

Clause 6.

The semiconductor device (A10) according to any one of Clauses 1 to 5, further comprising a first insulating film (31) located between the semiconductor element (10) and the re-wiring (40) in the thickness direction (z),
the first insulating film (31) is provided with a first opening (311) extending therethrough in the thickness direction (z) and exposing the electrode (21), and
a portion of the re-wiring (40) is received within the first opening (311).

Clause 7.

The semiconductor device (A10) according to Clause 6, further comprising a second insulating film (32) located on the first side (z1 side) in the thickness direction (z) with respect to
the first insulating film (31) and covering the re-wiring (40), the second insulating film (32) is provided with a second opening (321) and a third opening (322) each extending therethrough in the thickness direction (z) and exposing the re-wiring (40),
a portion of the first terminal (501) is received within the second opening (321), and
a portion of the second terminal (502) is received within the third opening (322).

Clause 8.

The semiconductor device (A10) according to Clause 7, wherein as viewed in the thickness direction (z), an area of the third opening (322) is greater than an area of the second opening (321).

Clause 9.

The semiconductor device (A10) according to Clause 7 or 8, wherein a dimension of the second insulating film (32) in the thickness direction (z) is greater than a dimension of the first insulating film (31) in the thickness direction (z).

Clause 10.

The semiconductor device (A10) according to any one of Clauses 7 to 9, wherein the first terminal (501) includes a first portion (51) received within the second opening (321) and a second portion (52) protruding beyond the second opening (321), and
as viewed in the thickness direction (z), the second portion (52) is located outside the second opening (321).

Clause 11.

The semiconductor device (A10) according to any one of Clauses 7 to 10, wherein the second terminal (502) includes a third portion (53) received within the third opening (322) and a fourth portion (54) protruding beyond the third opening (322), and
as viewed in the thickness direction (z), the fourth portion (54) is located outside the third opening (322).

Clause 12.

The semiconductor device (A10) according to any one of Clauses 7 to 11, wherein the re-wiring (40) includes a first base layer (40a) in contact with the electrode (21) and the first insulating film (31), and a first conductive layer (40b) stacked on the first base layer (40a).

Clause 13.

The semiconductor device (A10) according to Clause 12, wherein the terminal (50) includes a second base layer (50a) in contact with the re-wiring (40) and the second insulating film (32), and a second conductive layer (50b) stacked on the second base layer (50a).

Clause 14.

The semiconductor device (A30) according to any one of Clauses 1 to 13, further comprising a third insulating film (33) covering the semiconductor element (10) from a second side (z2 side) in the thickness direction (z).

Clause 15.

A method for manufacturing a semiconductor device (A10), the method comprising:
preparing a semiconductor element (10) provided with an electrode (21) on a first side (z1 side) in a thickness direction (z);
forming a first insulating film (31) on the first side (z1 side) in the thickness direction (z) of the semiconductor element (10), the first insulating film (31) including a first opening (311) that exposes the electrode (21);
forming a re-wiring (40) on the electrode (21) and a portion of the first insulating film (31), wherein a portion of the re-wiring (40) is received within the first opening (311) in the first insulating film (31);
forming a second insulating film (32) on the first side (z1 side) in the thickness direction (z) of the re-wiring (40), the second insulating film (32) including a second opening (321) and a third opening (322) each exposing a portion of the re-wiring (40);
forming a terminal (50) on a portion of the re-wiring (40) and a portion of the second insulating film (32), wherein a portion of the terminal (50) is received within the second opening (321) and the third opening (322) in the second insulating film (32); and
forming a conductive bonding layer (60) on the terminal (50),
wherein as viewed in the thickness direction (z), an area of the third opening (322) is greater than an area of the second opening (321), and
the forming of the conductive bonding layer (60) involves screen printing.

Clause 16.

The semiconductor device (A10) according to any one of Clauses 1 to 14, wherein the semiconductor element (10) includes a first circuit (121), and a second circuit (122) driven by the first circuit (121), and
the first terminal (501) is electrically connected to the first circuit (121), and the second terminal (502) is electrically connected to the second circuit (122).

REFERENCE NUMERALS

| | |
|---|---|
| A10, A20, A30: | semiconductor device |
| 10: | semiconductor element |
| 10A: | obverse surface |
| 11: | semiconductor substrate |
| 12: | semiconductor layer |
| 121: | first circuit |
| 122: | second circuit |
| 21: | electrode |
| 22: | passivation film |
| 221: | opening |
| 31: | first insulating film |
| 311: | first opening |
| 32: | second insulating film |
| 321: | second opening |
| 322: | third opening |
| 33: | third insulating film |
| 40: | re-wiring |
| 40a: | first base layer |
| 40b: | first conductive layer |
| 41: | main portion |
| 411: | first re-wiring portion |
| 412: | second re-wiring portion |
| 42: | contact portion |
| 50: | terminal |
| 50a: | second base layer |
| 50b: | second conductive layer |
| 501: | first terminal |
| 502: | second terminal |
| 51: | first portion |
| 52: | second portion |
| 53: | third portion |
| 54: | fourth portion |
| 60: | conductive bonding layer |
| 601: | first conductive bonding layer |
| 602: | second conductive bonding layer |
| 81: | first resist |
| 82: | second resist |
| 811, 821: | opening |
| 91: | screen |
| 911, 912: | slit |
| L1, L2, L3, L4: | length |
| t1, t2: | dimension |
| x: | first direction |
| y: | second direction |
| z: | thickness direction |

1. A semiconductor device comprising:
a semiconductor element;
an electrode located on a first side in a thickness direction of the semiconductor element;
a re-wiring located on the first side in the thickness direction with respect to the electrode and electrically connected to the electrode;
a terminal located on the first side in the thickness direction with respect to the re-wiring and electrically connected to the re-wiring; and
a conductive bonding layer located on the first side in the thickness direction with respect to the terminal and electrically connected to the terminal,
wherein the terminal includes a first terminal and a second terminal,
the conductive bonding layer includes a first conductive bonding layer electrically connected to the first terminal, and a second conductive bonding layer electrically connected to the second terminal,
as viewed in the thickness direction, an area of the second terminal is greater than an area of the first terminal, and
as viewed in the thickness direction, an area of the second conductive bonding layer is greater than an area of the first conductive bonding layer.

2. The semiconductor device according to claim 1, wherein as viewed in the thickness direction, the second conductive bonding layer overlaps with an entirety of the second terminal.

3. The semiconductor device according to claim 1, wherein the second terminal and the second conductive bonding layer extend in a first direction perpendicular to the thickness direction,
a length of the second terminal in the first direction is at least twice a length of the first terminal in the first direction, and
a length of the second conductive bonding layer in the first direction is at least twice a length of the first conductive bonding layer in the first direction.

4. The semiconductor device according to claim 1, wherein a length of the second terminal in a first direction perpendicular to the thickness direction is at least twice a length of the first terminal in the first direction, and
a length of the second terminal in a second direction perpendicular to the thickness direction and the first direction is at least twice a length of the first terminal in the second direction,
a length of the second conductive bonding layer in the first direction is at least twice a length of the first conductive bonding layer in the first direction, and
a length of the second conductive bonding layer in the second direction is at least twice a length of the first conductive bonding layer in the second direction.

5. The semiconductor device according to claim 1, wherein the conductive bonding layer is made of a material containing tin.

6. The semiconductor device according to claim 1, further comprising a first insulating film located between the semiconductor element and the re-wiring in the thickness direction,
the first insulating film is provided with a first opening extending therethrough in the thickness direction and exposing the electrode, and
a portion of the re-wiring is received within the first opening.

7. The semiconductor device according to claim 6, further comprising a second insulating film located on the first side in the thickness direction with respect to the first insulating film and covering the re-wiring,
the second insulating film is provided with a second opening and a third opening each extending therethrough in the thickness direction and exposing the re-wiring,
a portion of the first terminal is received within the second opening, and
a portion of the second terminal is received within the third opening.

8. The semiconductor device according to claim 7, wherein as viewed in the thickness direction, an area of the third opening is greater than an area of the second opening.

9. The semiconductor device according to claim 7, wherein a dimension of the second insulating film in the thickness direction is greater than a dimension of the first insulating film in the thickness direction.

10. The semiconductor device according to claim 7, wherein the first terminal includes a first portion received within the second opening and a second portion protruding beyond the second opening, and
as viewed in the thickness direction, the second portion extends outside beyond the second opening.

11. The semiconductor device according to claim 7, wherein the second terminal includes a third portion received within the third opening and a fourth portion protruding beyond the third opening, and
as viewed in the thickness direction, the fourth portion extends outside beyond the third opening.

12. The semiconductor device according to claim 7, wherein the re-wiring includes a first base layer in contact with the electrode and the first insulating film, and a first conductive layer stacked on the first base layer.

13. The semiconductor device according to claim 12, wherein the terminal includes a second base layer in contact with the re-wiring and the second insulating film, and a second conductive layer stacked on the second base layer.

14. The semiconductor device according to claim 1, further comprising a third insulating film covering the semiconductor element from a second side in the thickness direction.

15. A method for manufacturing a semiconductor device, the method comprising:
preparing a semiconductor element provided with an electrode on a first side in a thickness direction;
forming a first insulating film on the first side in the thickness direction of the semiconductor element, the first insulating film including a first opening that exposes the electrode;
forming a re-wiring on the electrode and a portion of the first insulating film in a manner such that a portion of the re-wiring is received within the first opening in the first insulating film;
forming a second insulating film on the first side in the thickness direction of the re-wiring, the second insulating film including a second opening and a third opening each exposing a portion of the re-wiring;
forming a terminal on a portion of the re-wiring and a portion of the second insulating film in a manner such that a portion of the terminal is received within the second opening and the third opening in the second insulating film; and
forming a conductive bonding layer on the terminal,
wherein as viewed in the thickness direction, an area of the third opening is greater than an area of the second opening, and
the forming of the conductive bonding layer involves screen printing.
